(19) United States
(12) Patent Application Publication
(10) Pub. No.: US 2024/0405168 A1
(43) Pub. Date: Dec. 5, 2024

(54) LIGHT-EMITTING DEVICE AND METHOD FOR MANUFACTURING THE SAME

(71) Applicant: Lextar Electronics Corporation, Hsinchu City (TW)

(72) Inventors: Yi-Chan YANG, Hsinchu City (TW); Wen-Syun WANG, Hsinchu City (TW); Te-Chung WANG, Hsinchu City (TW)

(21) Appl. No.: 18/675,511

(22) Filed: May 28, 2024

(30) Foreign Application Priority Data
May 31, 2023 (TW) 112120231

(51) Int. Cl. H01L 33/50; H01L 25/075; H01L 33/60; H01L 33/62

(52) U.S. Cl. CPC H01L 33/505; H01L 25/0753; H01L 33/60; H01L 33/62; H01L 2933/0041; H01L 2933/0058

(57) ABSTRACT

A light-emitting device is provided. The light-emitting device includes a circuit board and a connection board disposed on the circuit board and having a first pad, a second pad, and a third pad. The light-emitting device also includes a first light-emitting element disposed on the connection board and having a first electrode and a second electrode and a second light-emitting element adjacent to the first light-emitting element and having a third electrode and a fourth electrode. The light-emitting device further includes a light-converting layer disposed on the first light-emitting element and the second light-emitting element. The thermal expansion coefficient of the connection board is smaller than the thermal expansion coefficient of the circuit board.

### CROSS REFERENCE TO RELATED APPLICATIONS

This application claims priority of Taiwan Patent Application No. 112120231, filed on May 31, 2023, the entirety of which is incorporated by reference herein.

### BACKGROUND OF THE DISCLOSURE

### Field of the Disclosure

The present disclosure relates to a light-emitting device and a manufacturing method thereof, in particular to a light-emitting device capable of independently controlling each light-emitting element and/or having high light extraction efficiency and a manufacturing method thereof.

### Description of the Related Art

Light-emitting diodes (LEDs) operate on a different principle and have a different structure from traditional light sources, boasting advantages such as low power consumption, long component lifetime, no warm-up time, and fast response times. In addition, LEDs are small in size, shock-resistant, suitable for mass production, and easily made into extremely small or array-type components to meet application requirements. Therefore, they have a wide range of applications in the market. For example, LEDs can be used in various fields such as light-emitting devices, display devices, traffic signals, indicator devices, communication devices, illumination devices, and medical devices.

### BRIEF SUMMARY OF THE DISCLOSURE

An embodiment of the present disclosure provides a light-emitting device and a manufacturing method thereof, which include a circuit board and a connection board. In the light-emitting device according to the embodiment of the present disclosure, the light-emitting elements can be controlled independently, thereby achieving energy saving and being versatile for various applications (e.g., adaptive driving beam, ADB). In addition, the manufacturing method of the light-emitting device according to the embodiment of the present disclosure has advantages of low cost and low complexity.

Some embodiments of the present disclosure include a light-emitting device. The light-emitting device includes a circuit board and a connection board disposed on the circuit board and having a first pad, a second pad, and a third pad. The light-emitting device also includes a first light-emitting element having a first electrode and a second electrode disposed on the connection board and a second light-emitting element having a third electrode and a fourth electrode adjacent to the first light-emitting element. The light-emitting device further includes a light-converting layer disposed on the first light-emitting element and the second light-emitting element. The thermal expansion coefficient of the connection board is smaller than the thermal expansion coefficient of the circuit board.

Some embodiments of the present disclosure include a light-emitting device. The light-emitting device includes a circuit board and a connection board disposed on the circuit board. The light-emitting device also includes a first light-emitting element disposed on the connection board and a second light-emitting element adjacent to the first light-emitting element. The light-emitting device further includes a first isolation structure and a light-converting layer, the first isolation structure surrounds the first light-emitting element and the second light-emitting element and is disposed between the first light-emitting element and the second light-emitting element, and the light-converting layer is disposed on the first light-emitting element and the second light-emitting element. Moreover, the light-emitting device includes a second isolation structure surrounding the light-converting layer. The first isolation structure includes a reflective or scattering material, and the second isolation structure includes a light-absorbing material.

Some embodiments of the present disclosure include a method for manufacturing a light-emitting device. The method for manufacturing the light-emitting device includes the following steps. A first light-emitting element and a second light-emitting element are formed on a connection board. A first isolation structure is formed between and around the first light-emitting element and the second light-emitting element. A light-converting layer is formed on the first light-emitting element and the second light-emitting element. The light-converting layer is diced to form a plurality of light-converting segments that correspond to the first light-emitting element and the second light-emitting element. A second isolation structure is formed between and around the light-converting segments. The connection board is connected with a circuit board. The thermal expansion coefficient of the connection board is less than the thermal expansion coefficient of the circuit board.

### BRIEF DESCRIPTION OF THE DRAWINGS

Aspects of the embodiments of the present disclosure can be understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1 is a partial stereoscopic diagram of one stage of manufacturing the light-emitting device according to some embodiments of the present disclosure.

FIG. 2 is a partial stereoscopic diagram of one stage of manufacturing the light-emitting device according to some embodiments of the present disclosure.

FIG. 3 is a partial stereoscopic diagram of one stage of manufacturing the light-emitting device according to some embodiments of the present disclosure.

FIG. 4 is a partial stereoscopic diagram of one stage of manufacturing the light-emitting device according to some embodiments of the present disclosure.

FIG. 5 is a partial stereoscopic diagram of one stage of manufacturing the light-emitting device according to some embodiments of the present disclosure.

FIG. 6 is a partial stereoscopic diagram of one stage of manufacturing the light-emitting device according to some embodiments of the present disclosure.

FIG. 7 is a partial stereoscopic diagram of one stage of manufacturing the light-emitting device according to some embodiments of the present disclosure.

FIG. 8 is a partial exploded view illustrating the light-emitting device in FIG. 7 according to some embodiments of the present disclosure.

FIG. 9 is a partial top view illustrating a portion of the circuit board and the connection board according to some embodiments of the present disclosure.

FIG. 10 is a partial top view illustrating the circuit board according to some embodiments of the present disclosure.

FIG. 11 is a top view illustrating the circuit board according to some embodiments of the present disclosure.

FIG. 12 is a partial cross-sectional view illustrating the light-emitting device in FIG. 7 according to some embodiments of the present disclosure.

FIG. 13 is a partial cross-sectional view illustrating the light-emitting device in FIG. 7 according to some other embodiments of the present disclosure.

FIG. 14 is a partial cross-sectional view illustrating the light-emitting device in FIG. 7 according to some other embodiments of the present disclosure.

### DETAILED DESCRIPTION OF THE DISCLOSURE

The following disclosure provides different embodiments or examples for implementing different features of the subject matter provided. Specific examples of components and arrangements are described below to simplify the present disclosure. These are, of course, merely examples and are not intended to be limiting. For example, a first feature is formed on a second feature in the description that follows may include embodiments in which the first feature and second feature are formed in direct contact, and may also include embodiments in which additional features may be formed between the first feature and second feature, so that the first feature and second feature may not be in direct contact.

It should be understood that additional steps may be implemented before, during, or after the illustrated methods, and some steps might be replaced or omitted in other embodiments of the illustrated methods.

Furthermore, spatially relative terms, such as “beneath,” “below,” “lower,” “on,” “above,” “upper” and the like, may be used herein for ease of description to describe one element or feature's relationship to other elements or features as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In the present disclosure, the terms “about,” “approximately” and “substantially” typically mean +/−20% of the stated value, more typically +/−10% of the stated value, more typically +/−5% of the stated value, more typically +/−3% of the stated value, more typically +/−2% of the stated value, more typically +/−1% of the stated value and even more typically +/−0.5% of the stated value. The stated value of the present disclosure is an approximate value. That is, when there is no specific description of the terms “about,” “approximately” and “substantially”, the stated value includes the meaning of “about,” “approximately” or “substantially”.

Unless otherwise defined, all terms (including technical and scientific terms) used herein have the same meaning as commonly understood by one of ordinary skill in the art to which this disclosure belongs. It should be understood that terms such as those defined in commonly used dictionaries should be interpreted as having a meaning that is consistent with their meaning in the context of the relevant art and will not be interpreted in an idealized or overly formal sense unless expressly so defined in the embodiments of the present disclosure.

The present disclosure may repeat reference numerals and/or letters in following embodiments. This repetition is for the purpose of simplicity and clarity and does not in itself dictate a relationship between the various embodiments and/or configurations discussed.

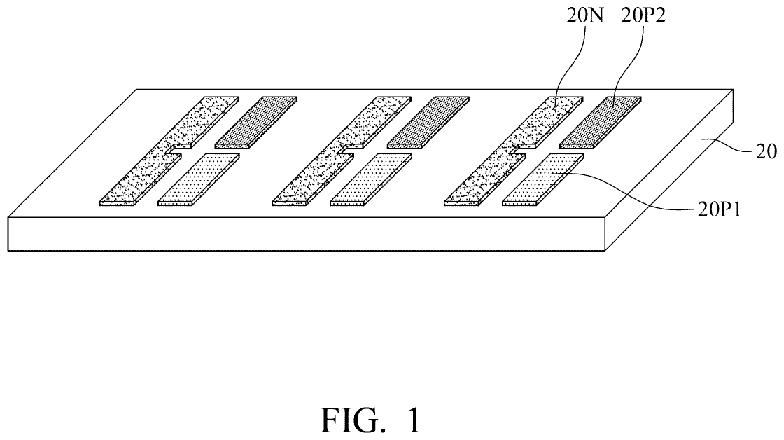

FIG. 1 to FIG. 7 are partial stereoscopic diagrams of various stages of manufacturing the light-emitting device 100 according to some embodiments of the present disclosure. It should be noted that, for the sake of simplicity, some components of the light-emitting device 100 have been omitted in FIG. 1 to FIG. 7.

Referring to FIG. 1, in some embodiments, a connection board 20 is provided. The connection board 20 has multiple first pads 20N, multiple second pads 20P1, and multiple third pads 20P2. For example, as shown in FIG. 1, a first pad 20N may be arranged adjacent to a second pad 20P1 and a third pad 20P2 to form a group of electrical connection structures. The connection board 20 may include multiple groups of electrical connection structures that are arranged in a row (or an array). However, the present disclosure is not limited thereto.

In some embodiments, the connection board 20 is a ceramic substrate, and the first pads 20N, the second pads 20P1, and the third pads 20P2 include conductive materials such as metals, metal silicides, similar materials, or combinations thereof. For example, the metal may include gold (Au), nickel (Ni), platinum (Pt), palladium (Pd), iridium (Ir), titanium (Ti), chromium (Cr), tungsten (W), aluminum (Al), copper (Cu), the like, an alloy thereof, or a combination thereof. In some embodiments, the first pads 20N, the second pads 20P1, and the third pads 20P2 may be formed by physical vapor deposition (PVD), chemical vapor deposition (CVD), atomic layer deposition (ALD), evaporation, sputtering, the like, or a combination thereof. However, the present disclosure is not limited thereto.

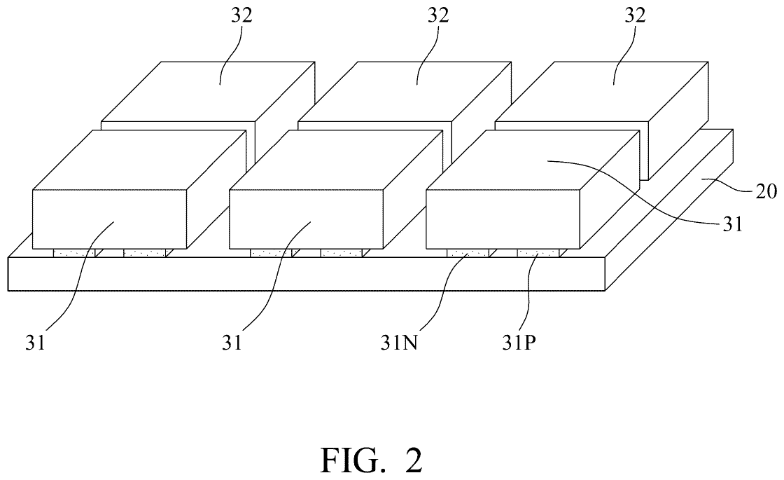

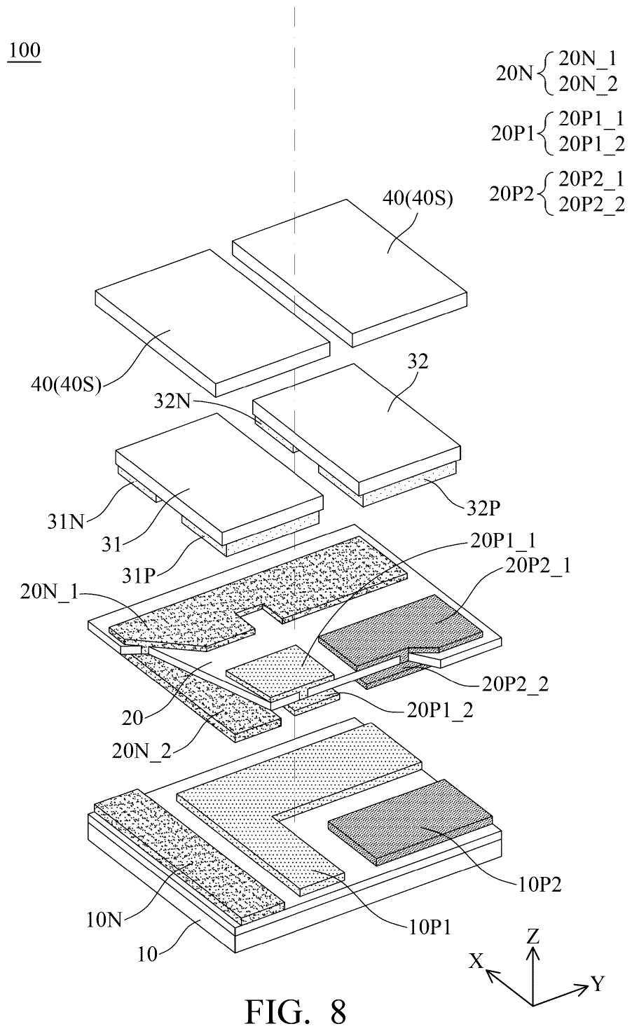

Referring to FIG. 2, in some embodiments, a first light-emitting element 31 and a second light-emitting element 32 are formed on the connection board 20, and the second light-emitting element 32 is adjacent to the first light-emitting element 31. In this embodiment, there are multiple first light-emitting elements 31 and multiple second light-emitting elements 32 on the connection board 20, and these first light-emitting elements 31 and second light-emitting elements 32 are arranged in a row or an array. As shown in FIG. 2, in some embodiments, each first light-emitting element 31 has a first electrode 31N and a second electrode 31P, and each second light-emitting element 32 has a third electrode 32N and a fourth electrode 32P (shown in FIG. 8).

In some embodiments, the first light-emitting element 31 and the second light-emitting element 32 are micro LED chips. The micro LED chip may include an n-type semiconductor layer, a light-emitting layer, and a p-type semiconductor layer (not detailed), and the light-emitting layer is between the n-type semiconductor layer and the p-type semiconductor layer. The n-type semiconductor layer, the light-emitting layer, and the p-type semiconductor layer may be formed by an epitaxial growth process, but the present disclosure is not limited thereto. The light emitted by the micro LED chip is determined by the light-emitting layer. In this embodiment, both the first light-emitting element 31 and the second light-emitting element 32 emit blue light. That is, the light-emitting layers of the first light-emitting element 31 and the second light-emitting element 32 may emit blue light, but the present disclosure is not limited thereto.

The n-type semiconductor layer may include II-VI group materials (e.g., zinc selenide (ZnSe)) or III-V group materials (e.g., gallium nitride (GaN), aluminum nitride (AlN), indium nitride (InN), indium gallium nitride (InGaN), aluminum gallium nitride (AlGaN) or aluminum indium gallium nitride (AlInGaN)), and the n-type semiconductor layer may include dopants such as silicon (Si) or germanium (Ge), but the present disclosure is not limited thereto.

The light-emitting layer may include one undoped semiconductor layer or at least one lightly doped layer. For example, the light-emitting layer may be a quantum well (QW) layer, which may include indium gallium nitride (InₓGa₁₋ₓN), gallium nitride (GaN), aluminum gallium nitride (AlGaN) or aluminum indium gallium nitride (AlInGaN), but the present disclosure is not limited thereto. Alternatively, the light-emitting layer may also be a multiple quantum well (MQW) layer.

The p-type semiconductor layer may include II-VI group materials (e.g., zinc selenide (ZnSe)) or III-V group materials (e.g., gallium nitride (GaN), aluminum nitride (AlN), indium nitride (InN), indium gallium nitride (InGaN), aluminum gallium nitride (AlGaN) or aluminum indium gallium nitride (AlInGaN)), and the p-type semiconductor layer may include dopants such as magnesium (Mg), carbon (C), but the present disclosure is not limited thereto. Additionally, the n-type semiconductor layer and the p-type semiconductor layer may be a single layer or multilayer structure.

Furthermore, the first electrode 31N of the first light-emitting element 31 is electrically connected to the n-type semiconductor layer of the first light-emitting element 31, and the second electrode 31P of the first light-emitting element 31 is electrically connected to the p-type semiconductor layer of the first light-emitting element 31. Similarly, the third electrode 32N of the second light-emitting element 32 is electrically connected to the n-type semiconductor layer of the second light-emitting element 32, and the fourth electrode 32P of the second light-emitting element 32 is electrically connected to the p-type semiconductor layer of the second light-emitting element 32. For example, the first electrode 31N and the second electrode 31P of the first light-emitting element 31 and the third electrode 32N and the fourth electrode 32P of the second light-emitting element 32 include conductive materials, the examples of which have been mentioned above and will not be repeated here.

As shown in FIG. 1 and FIG. 2 (and later FIG. 8), in some embodiments, the first electrode 31N of the first light-emitting element 31 and the third electrode 32N of the second light-emitting element 32 are electrically connected to the first pad 20N, the second electrode 31P of the first light-emitting element 31 is electrically connected to the second pad 20P1, and the fourth electrode 32P of the second light-emitting element 32 is electrically connected to the third pad 20P2. In other words, the first electrode 31N of the first light-emitting element 31 and the corresponding (i.e., adjacent) third electrode 32N of the second light-emitting element 32 may share the same pad.

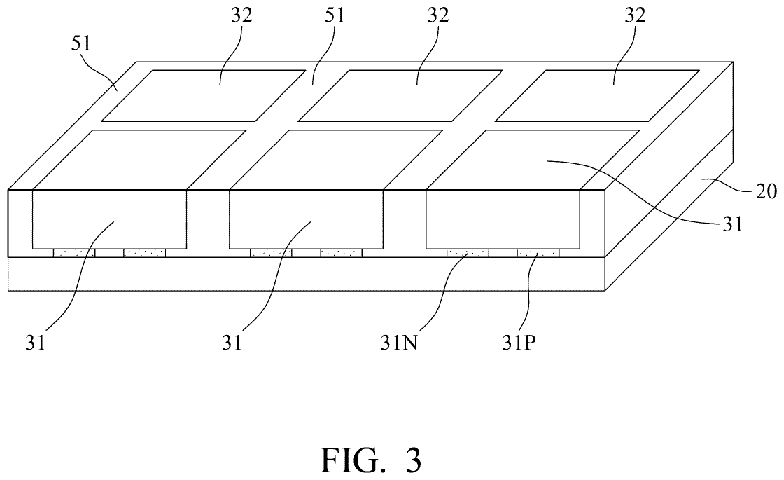

Referring to FIG. 3, in some embodiments, a first isolation structure 51 is formed between and around the first light-emitting element 31 and the second light-emitting element 32. In other words, the first isolation structure 51 surrounds the periphery of multiple first light-emitting elements 31 and second light-emitting elements 32 and is disposed between the first light-emitting element 31 and the second light-emitting element 32. In some embodiments, the first isolation structure 51 includes reflective or scattering materials and transparent adhesive materials. Reflective or scattering materials include titanium dioxide (TiO₂) or silicon oxide (SiOₓ), and transparent adhesive materials include silicone resin, epoxy resin, or B-stage resin, but the present disclosure is not limited thereto. B-stage resin refers to a two-stage thermosetting adhesive that requires secondary baking to be fully cured. B-stage refers to the reaction between the resin and the curing agent to form a semi-cured solid, which can become fully cured after further heat curing. In some embodiments, the first isolation structure 51 is formed by mixing TiO₂ microparticles with a silicone resin uniformly, with a weight percentage wt %>20% and a particle size<1 μm, to form a white adhesive, but the present disclosure is not limited thereto.

Here, the first isolation structure 51 (e.g., the white adhesive) may reflect/scatter the light emitted by the first light-emitting element 31 and the second light-emitting element 32 (e.g., blue light) to direct the lights emit upwards as much as possible, thereby greatly improving the upward light emission efficiency of the first light-emitting element 31 and the second light-emitting element 32.

In some other embodiments, the first isolation structure 51 includes light-absorbing materials to reduce the crosstalk of each light-emitting element emitting light sideways, for example, the light from the first light-emitting element 31 leaks into the second light-emitting element 32 when the first light-emitting element 31 is selectively turned on and the second light-emitting element 32 is selectively turned off, which causes the dark area not as dark as expected. In some embodiments, light-absorbing materials include black carbon powder, but the present disclosure is not limited thereto. The first isolation structure 51 may be a black adhesive. In some embodiments, the first isolation structure 51 is formed by mixing black carbon powder with a silicone resin uniformly, with a weight percentage wt %>1% and a particle size<5 μm, to form a black adhesive.

In some other embodiments, the first isolation structure 51 includes both light-absorbing materials and reflective/scattering materials, having both reflection and absorption of light emitted sideways from the first light-emitting element 31 and the second light-emitting element 32, to enhance the upward light emission efficiency of each light-emitting element and reduce the crosstalk from the light emitted sideways by each light-emitting element.

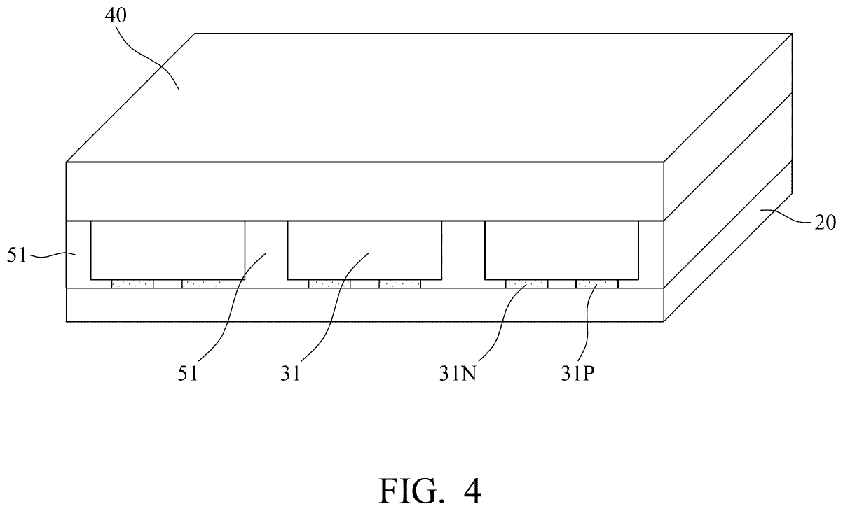

Referring to FIG. 4, in some embodiments, a light-converting layer 40 is formed on the first light-emitting element 31 and the second light-emitting element 32. In this embodiment, the light-converting layer 40 is phosphor glass, which is made by dispersing phosphor uniformly in glass using a low melting temperature technique that can effectively improve the thermal quenching of fluorescence. In some embodiments, the light-converting layer 40 converts part of the light (e.g., blue light) emitted by the first light-emitting element 31 and the second light-emitting element 32 into yellow light, and the light from the first light-emitting element 31 and the second light-emitting element 32 that is not absorbed (e.g., blue light) can be mixed with the light from the light-converting layer 40 (e.g., yellow light) to form white light, but the present disclosure is not limited thereto. In some embodiments, the method for forming a light-converting layer 40 on the first light-emitting element 31 and the second light-emitting element 32 further includes using a transparent silicone resin (not shown in the figure) to attach the light-converting layer 40 to the first light-emitting element 31 and the second light-emitting element 32.

The colors of the light emitted by the first light-emitting element 31 and the second light-emitting element 32, and the color of the light from the light-converting layer 40 (or the color converted from the light emitted by the first light-emitting element 31 and the second light-emitting element 32) can be adjusted according to actual needs.

In some embodiments, as shown in FIG. 2, after electrically connecting the first light-emitting element 31 and the second light-emitting element 32 to the connection board 20, a transparent silicone resin (not drawn in the figure) may be used to attach the light-converting layer 40 to the top surfaces of the first light-emitting element 31 and the second light-emitting element 32. Then, the injection compression molding process is used to fill the sides and bottom of the first light-emitting element 31 and the second light-emitting element 32 with white or black adhesive material (i.e., the first isolation structure 51) to complete a structure similar to that shown in FIG. 4.

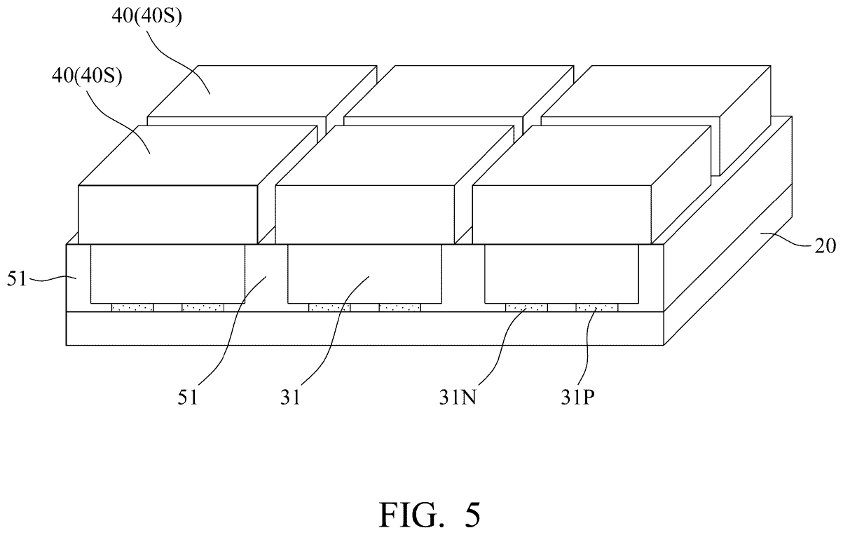

Referring to FIG. 5, in some embodiments, the light-converting layer 40 is diced to form multiple light-converting segments 40S correspond to the first light-emitting element 31 and the second light-emitting element 32. For example, the light-converting layer 40 may be diced with a very small spacing (e.g., less than 50 μm) to form grooves and multiple separated (or partially connected) light-converting segments 40S.

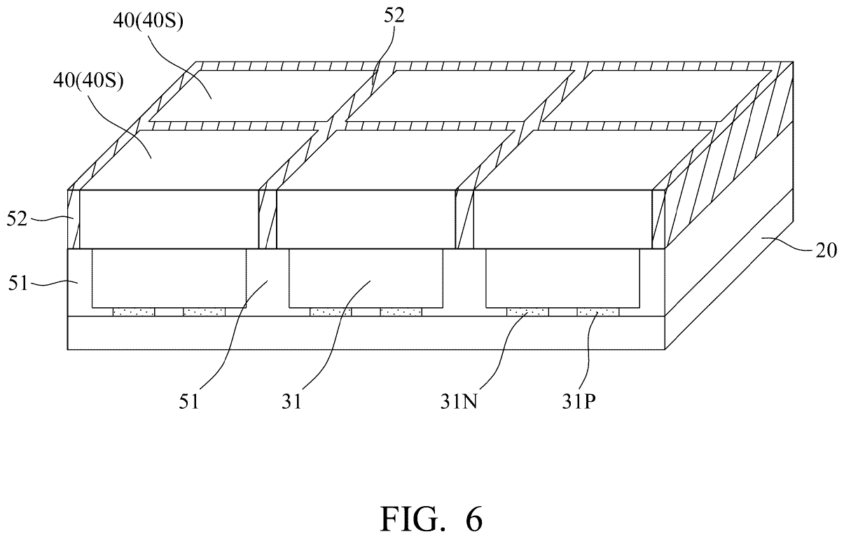

Then, referring to FIG. 6, in some embodiments, a second isolation structure 52 is formed between and around these light-converting segments 40S. In other words, in this embodiment, the second isolation structure 52 surrounds the light-converting layer 40, and a portion of the second isolation structure 52 is within the light-converting layer 40, dividing the light-converting layer 40 into multiple light-converting segments 40S that respectively correspond to the first light-emitting element 31 and the second light-emitting element 32.

In some embodiments, the second isolation structure 52 includes light-absorbing materials. For example, light-absorbing materials include black carbon powder, but the present disclosure is not limited thereto. The second isolation structure 52 may be a black adhesive. In some embodiments, the second isolation structure 52 is formed by mixing black carbon powder with a silicone resin uniformly, with a weight percentage wt %>1% and a particle size<5 μm, to form a black adhesive.

The second isolation structure 52 may absorb the light scattered sideways in the light-converting segment 40S, forming unidirectional light output upwards, thereby significantly enhancing the contrast between the brightness and darkness of the light (e.g., white light), and reducing cross talk between two adjacent first light-emitting elements 31, two adjacent second light-emitting elements 32, or adjacent first light-emitting element 31 and second light-emitting element 32.

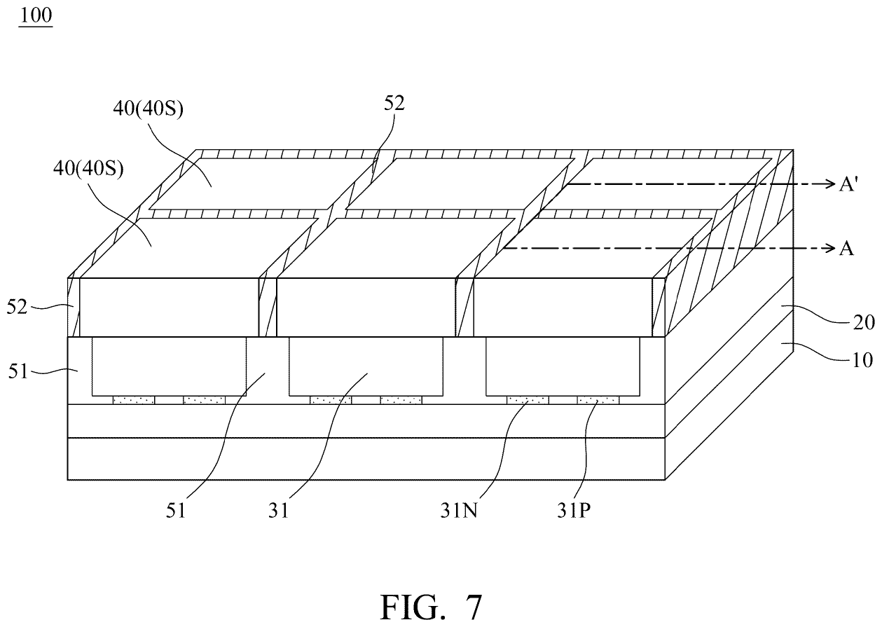

Referring to FIG. 7, in some embodiments, the connection board 20 is connected to the circuit board 10 to form a light-emitting device 100. In more detail, the circuit board 10 is disposed on a side of the connection board 20 opposite to the first light-emitting element 31 and the second light-emitting element 32. In some embodiments, the thermal expansion coefficient of the connection board 20 is less than the thermal expansion coefficient of the circuit board 10. In some embodiments, the circuit board 10 is a copper foil substrate, and the connection board 20 is a ceramic substrate, but the present disclosure is not limited thereto. Because the connection board 20 (e.g., a ceramic substrate) and the circuit board 10 (e.g., a copper foil substrate) may form a downward heat dissipation path, thereby effectively improving the overall heat dissipation performance of the light-emitting device 100.

As shown in FIG. 1 to FIG. 7, in some embodiments, the light-emitting device 100 includes a circuit board 10 and a connection board 20. The connection board 20 is disposed on the circuit board 10 and has a first pad 20N, a second pad 20P1, and a third pad 20P2. The light-emitting device 100 also includes a first light-emitting element 31 and a second light-emitting element 32. The first light-emitting element 31 is disposed on the connection board 20 and has a first electrode 31N and a second electrode 31P. The second light-emitting element 32 is adjacent to the first light-emitting element 31 and has a third electrode 32N and a fourth electrode 32P. The light-emitting device 100 further includes a light-converting layer 40, which is disposed on the first light-emitting element 31 and the second light-emitting element 32. In the embodiments of the present disclosure, the thermal expansion coefficient of the connection board 20 is less than the thermal expansion coefficient of the circuit board 10.

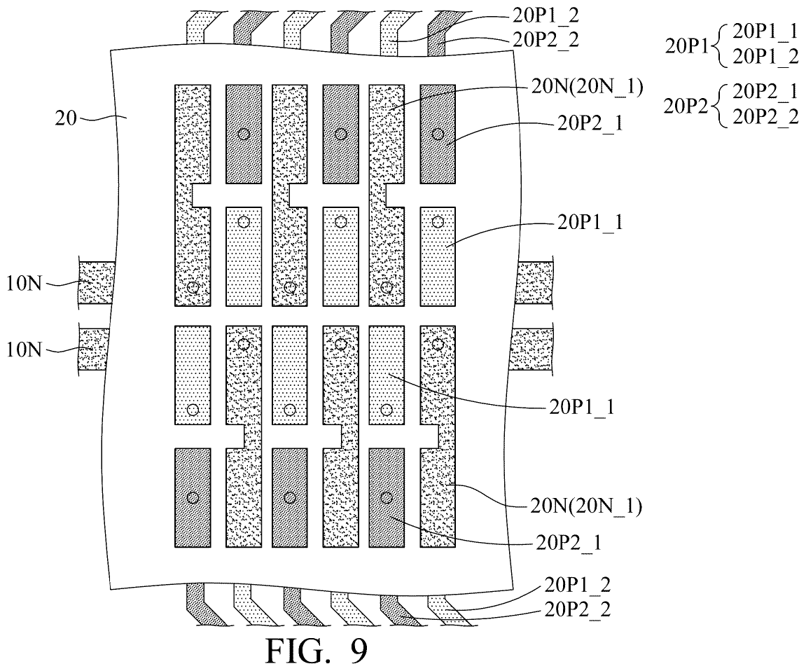

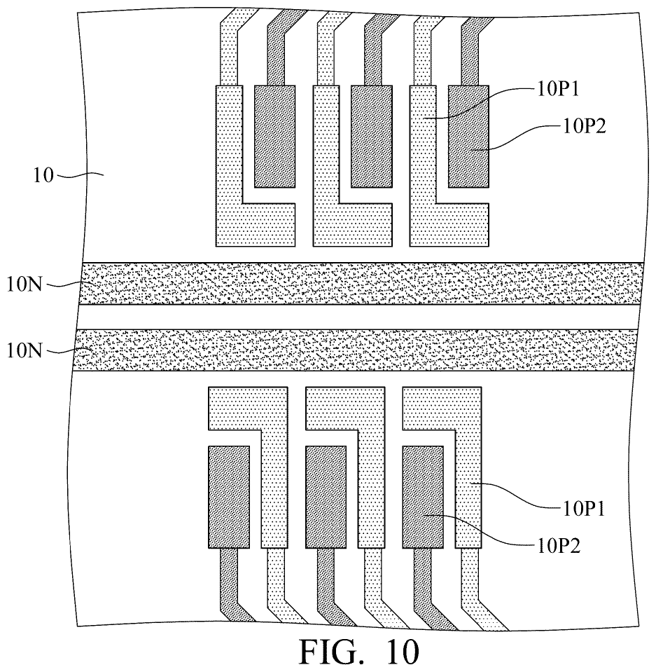

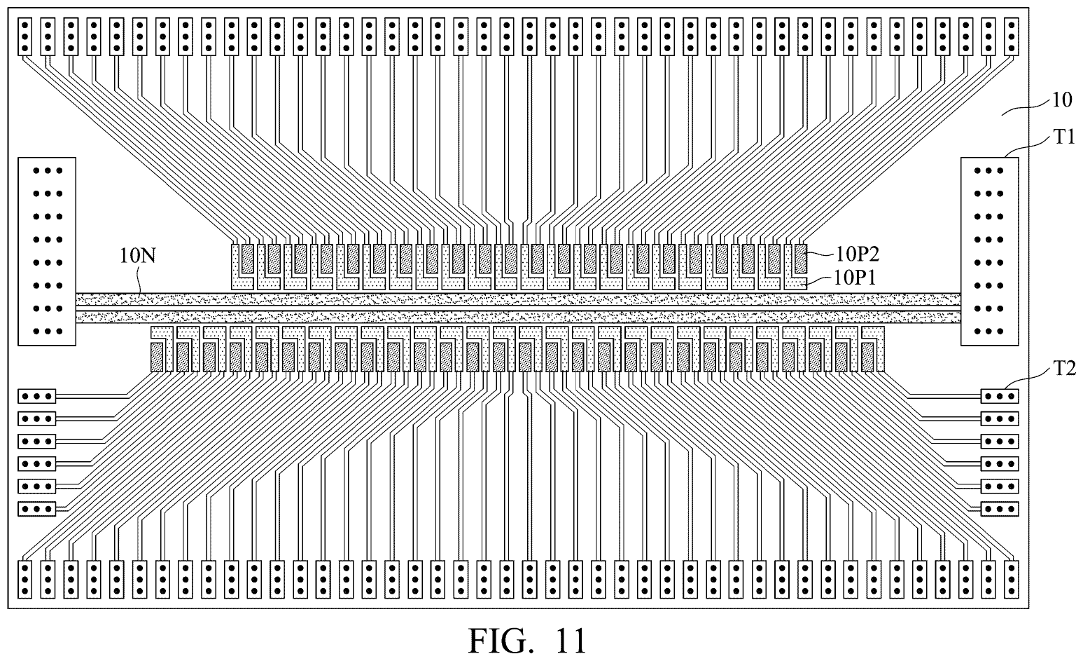

FIG. 8 is a partial exploded view illustrating the light-emitting device 100 in FIG. 7 according to some embodiments of the present disclosure. FIG. 9 is a partial top view illustrating a portion of the circuit board 10 and the connection board 20 according to some embodiments of the present disclosure. FIG. 10 is a partial top view illustrating the circuit board 10 according to some embodiments of the present disclosure. FIG. 11 is a top view illustrating the circuit board 10 according to some embodiments of the present disclosure. Similarly, for the sake of simplicity, some components have been omitted in FIG. 8 to FIG. 11.

Referring to FIG. 8 to FIG. 11, in some embodiments, the circuit board 10 has one first conductive wire 10N (two first conductive wires 10N are shown in FIG. 9 to FIG. 11), multiple second conductive wires 10P1, and multiple third conductive wires 10P2. In addition, in some embodiments, each first pad 20N is electrically connected to the first conductive wire 10N, each second pad 20P1 is electrically connected to the corresponding second conductive wire 10P1, and each third pad 20P2 is electrically connected to the corresponding third conductive wire 10P2. In some embodiments, the first pad 20N, the second pad 20P1, and the third pad 20P2 pass through the connection board 20 (e.g., including an insulating ceramic substrate), and the top view shapes of these three pads correspond to the four electrodes of the corresponding first light-emitting element 31 and second light-emitting element and 32, and the bottom view shapes of these three pads correspond to the three conductive wires on the circuit board 10.

In more detail, in order to accommodate more light-emitting elements to form an array, a part of the first pad 20N above the connection board 20 (i.e., the first pad 20N_1 shown in FIG. 8) extends longitudinally (e.g., in the Y-direction in FIG. 8) and is simultaneously connected (electrically) to the corresponding pair of the first light-emitting element 31 and the second light-emitting element 32. A part of the first pad 20N below the connection board 20 (i.e., the first pad 20N_2 shown in FIG. 8) extends laterally (e.g., in the X-direction in FIG. 8) to connect all first pads 20N above the connection board 20 of the laterally expanded light-emitting element array (i.e., the first pad 20N_1 shown in FIG. 9) together to electrically connect to the first conductive wire 10N of the circuit board 10.

Multiple second pads 20P1 and multiple third pads 20P2 respectively connect (electrically) to the corresponding first light-emitting element 31 and the corresponding second light-emitting element 32 above the connection board 20 (i.e., the second pad 20P1_1 and the third pad 20P2_1 shown in FIG. 8). Multiple second pads 20P1 and multiple third pads 20P2 below the connection board 20 respectively connect (electrically) to the corresponding second conductive wire 10P1 and the corresponding third conductive wire 10P2 (i.e., the second pad 20P1_2 and the third pad 20P2_2 shown in FIG. 8). In some embodiments, one first conductive wire 10N extends laterally (e.g., in the X-direction in FIG. 8) on the circuit board 10, and multiple second conductive wires 10P1 and multiple third conductive wires 10P2 extend longitudinally (e.g., in the Y-direction in FIG. 8) on the circuit board 10.

As shown in FIG. 8 to FIG. 11, in this embodiment, the connection board 20 uses the design of conductive holes to connect the first electrodes 31N of multiple first light-emitting elements 31 and the third electrodes 32N of multiple second light-emitting elements 32 together at a common electrode through the corresponding first pad 20N. The first pad 20N extends laterally below the connection board 20 and connect (electrically) to the first conductive wire 10N of the circuit board 10. Conversely, the second electrodes 31P of multiple first light-emitting elements 31 and the fourth electrodes 32P of multiple second light-emitting elements 32 are respectively connected to the corresponding second pads 20P1 and the third pads 20P2. The second pads 20P1 and the third pads 20P2 extend longitudinally below the connection board 20 and are separately connected (electrically) to the second conductive wires 10P1 and the third conductive wires 10P2 of the circuit board 10. However, the present disclosure is not limited thereto.

In some other embodiments, the polarity of all the electrodes of the light-emitting elements may be reversed. The second electrodes 31P of multiple first light-emitting elements 31 and the fourth electrodes 32P of multiple second light-emitting elements 32 may be connected together at a common electrode, while the first electrodes 31N of multiple first light-emitting elements 31 and the third electrodes 32N of multiple second light-emitting elements 32 are separately connected to corresponding pads.

In the aforementioned embodiments, through the first pad 20N, the second pad 20P1, and the third pad 20P2 of the connection board 20, and the first conductive wire 10N, the second conductive wire 10P1, and the third conductive wire 10P2 of the circuit board 10, the lateral/longitudinal circuit may be extended outward to connect to the terminals T1 and T2 arranged around the periphery of the circuit board 10 as shown in FIG. 11. Moreover, in the array formed by multiple first light-emitting elements 31 and multiple second light-emitting elements 32, each first light-emitting element 31 and each second light-emitting element 32 can be independently controlled.

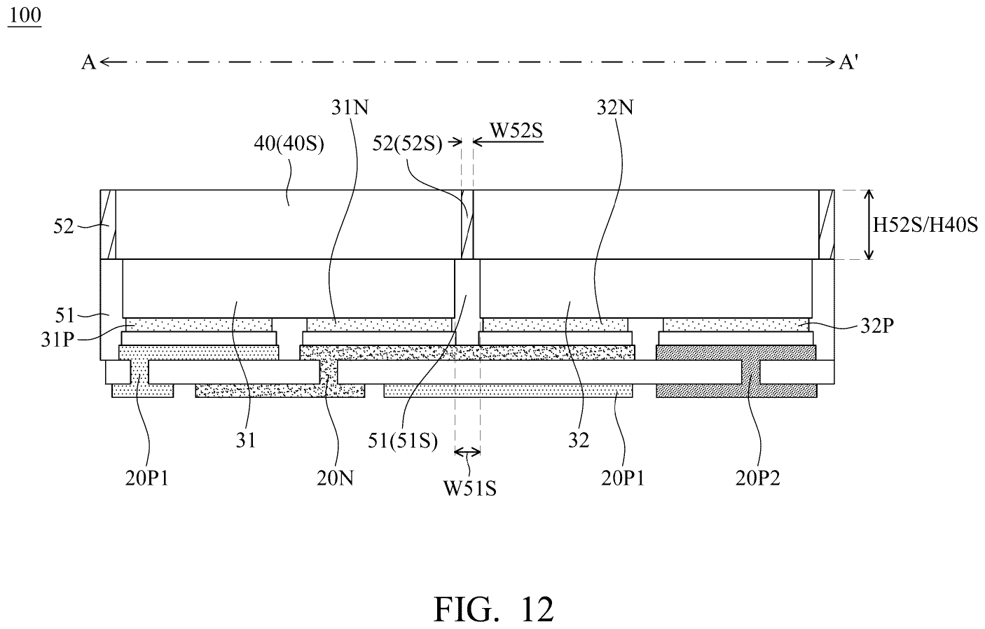

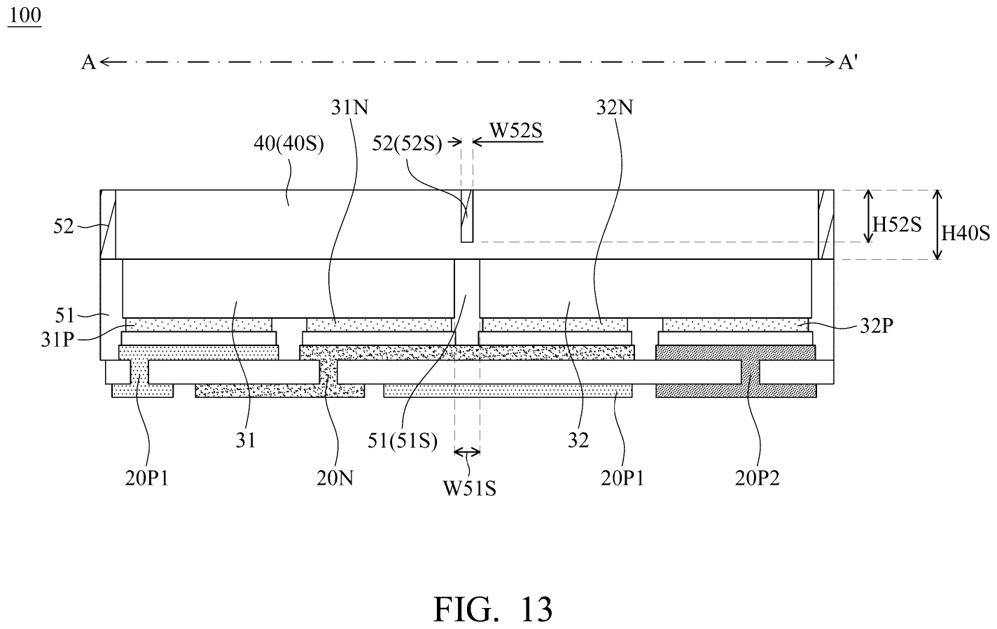

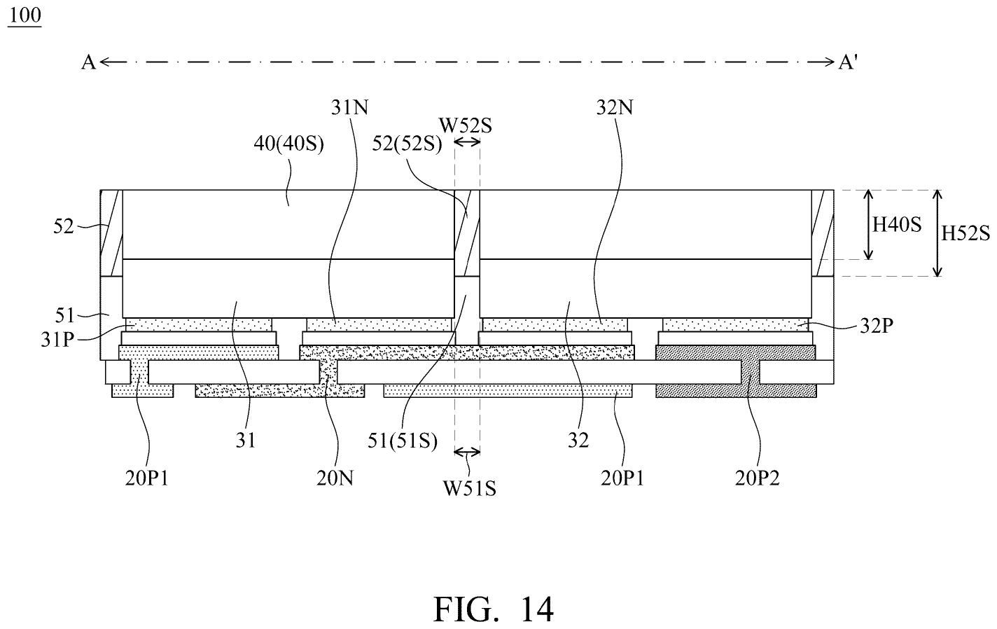

FIG. 12 is a partial cross-sectional view illustrating the light-emitting device 100 in FIG. 7 according to some embodiments of the present disclosure. FIG. 13 is a partial cross-sectional view illustrating the light-emitting device 100 in FIG. 7 according to some other embodiments of the present disclosure. FIG. 14 is a partial cross-sectional view illustrating the light-emitting device 100 in FIG. 7 according to some other embodiments of the present disclosure. Similarly, for the sake of simplicity, some components of the light-emitting device 100 have been omitted in FIG. 12 to FIG. 14.

As shown in FIG. 12 to FIG. 14, in some embodiments, in a cross-sectional view, the first isolation structure 51 is divided into multiple first isolation segments 51S, and the second isolation structure 52 is divided into multiple second isolation segments 52S. The second isolation segments 52S correspond to the first isolation segments 51S.

Referring to FIG. 12, in this embodiment, the width W52S of each second isolation segment 52S is smaller than the width W51S of each first isolation segment 51S, and the height H52S of the second isolation segment 52S in the light-converting layer 40 is equal to the thickness H40S of the light-converting layer 40.

Referring to FIG. 13, in this embodiment, the width W52S of each second isolation segment 52S is smaller than the width W51S of each first isolation segment 51S, and the height H52S of the second isolation segment 52S in the light-converting layer 40 is smaller than the thickness H40S of the light-converting layer 40.

Referring to FIG. 14, in this embodiment, the width W52S of each second isolation segment 52S is smaller than or equal to the width W51S of each first isolation segment 51S, and the second isolation structure 52 further extends to a space between the first light-emitting component 31 and the second light-emitting component 32.

In summary, according to the embodiments of the present disclosure, the light-emitting device includes a circuit board and a connection board disposed on the circuit board. Therefore, the light-emitting elements can be controlled independently and have a good heat dissipation path. This allows for energy-saving and application in many different fields (e.g., adaptive driving beam (ADB)). Furthermore, the method for manufacturing the light-emitting device according to the embodiments of the present disclosure has advantages of low cost and low complexity.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure. Therefore, the scope of protection should be determined through the claims. In addition, although some embodiments of the present disclosure are disclosed above, they are not intended to limit the scope of the present disclosure.

Reference throughout this specification to features, advantages, or similar language does not imply that all of the features and advantages that may be realized with the present disclosure should be or are in any single embodiment of the disclosure. Rather, language referring to the features and advantages is understood to mean that a specific feature, advantage, or characteristic described in connection with an embodiment is included in at least one embodiment of the present disclosure. Thus, discussions of the features and advantages, and similar language, throughout this specification may, but do not necessarily, refer to the same embodiment.

Furthermore, the described features, advantages, and characteristics of the disclosure may be combined in any suitable manner in one or more embodiments. One skilled in the relevant art will recognize, in light of the description herein, that the disclosure can be practiced without one or more of the specific features or advantages of a particular embodiment. In other instances, additional features and advantages may be recognized in certain embodiments that may not be present in all embodiments of the disclosure.

What is claimed is:

1. A light-emitting device, comprising:
a circuit board;
a connection board disposed on the circuit board and having a first pad, a second pad, and a third pad;
a first light-emitting element disposed on the connection board and having a first electrode and a second electrode;
a second light-emitting element adjacent to the first light-emitting element and having a third electrode and a fourth electrode; and
a light-converting layer disposed on the first light-emitting element and the second light-emitting element;
wherein a thermal expansion coefficient of the connection board is less than a thermal expansion coefficient of the circuit board.

2. The light-emitting device as claimed in claim 1, wherein the first electrode and the third electrode are electrically connected to the first pad, the second electrode is electrically connected to the second pad, and the fourth electrode is electrically connected to the third pad.

3. The light-emitting device as claimed in claim 2, wherein the circuit board has a first conductive wire, a second conductive wire, and a third conductive wire, the first pad is electrically connected to the first conductive wire, the second pad is electrically connected to the second conductive wire, and the third pad is electrically connected to the third conductive wire.

4. The light-emitting device as claimed in claim 2, further comprising a plurality of first light-emitting elements and a plurality of second light-emitting elements, wherein the first light-emitting elements and the second light-emitting elements are arranged in a row or an array.

5. The light-emitting device as claimed in claim 4, wherein the connection board has a plurality of first pads, a plurality of second pads, and a plurality of third pads.

6. The light-emitting device as claimed in claim 5, wherein the circuit board has at least one first conductive wire, a plurality of second conductive wires, and a plurality of third conductive wires, each of the first pads is electrically connected to the at least one first conductive wire, each of the second pads is electrically connected to a corresponding one of the second conductive wires, and each of the third pads is electrically connected to a corresponding one of the third conductive wires.

7. The light-emitting device as claimed in claim 1, wherein the circuit board is a copper foil substrate, and the connection board is a ceramic substrate.

8. The light-emitting device as claimed in claim 1, further comprising:
a first isolation structure surrounding the first light-emitting element and the second light-emitting element and disposed between the first light-emitting element and the second light-emitting element.

9. The light-emitting device as claimed in claim 8, further comprising:
a second isolation structure dividing the light-converting layer into a plurality of light-converting segments, wherein the light-converting segments respectively correspond to the first light-emitting element and the second light-emitting element.

10. The light-emitting device as claimed in claim 9, wherein in a cross-sectional view, the first isolation structure is divided into a plurality of first isolation segments, the second isolation structure is divided into a plurality of second isolation segments, the second isolation segments correspond to the first isolation segments, and a width of each of the second isolation segments is less than or equal to a width of each of the first isolation segments.

11. The light-emitting device as claimed in claim 9, wherein the first isolation structure and the second isolation structure comprise a light-absorbing material.

12. The light-emitting device as claimed in claim 9, wherein the first isolation structure comprises a reflective or scattering material, and the second isolation structure comprises a light-absorbing material.

13. A light-emitting device, comprising:
a circuit board;
a connection board disposed on the circuit board;
a first light-emitting element disposed on the connection board;
a second light-emitting element adjacent to the first light-emitting element;
a first isolation structure surrounding the first light-emitting element and the second light-emitting element and disposed between the first light-emitting element and the second light-emitting element;
a light-converting layer disposed on the first light-emitting element and the second light-emitting element; and
a second isolation structure surrounding the light-converting layer;
wherein the first isolation structure comprises a reflective or scattering material, and the second isolation structure comprises a light-absorbing material.

14. The light-emitting device as claimed in claim 13, wherein at least a portion of the second isolation structure is within the light-converting layer and divides the light-converting layer into a plurality of light-converting segments, and the light-converting segments respectively correspond to the first light-emitting element and the second light-emitting element.

15. The light-emitting device as claimed in claim 14, wherein in a cross-sectional view, the second isolation structure is divided into a plurality of second isolation segments, a height of the second isolation segments within the light-converting layer is less than or equal to a thickness of the light-converting layer.

16. The light-emitting device as claimed in claim 14, wherein the second isolation structure further extends into a space between the first light-emitting element and the second light-emitting element.

17. The light-emitting device as claimed in claim 13, wherein the light-converting layer is a phosphor glass.

18. The light-emitting device as claimed in claim 13, wherein the first light-emitting element and the second light-emitting element emit blue light, and the light-converting layer converts part of a light emitted by the first light-emitting element and the second light-emitting element into yellow light.

19. A method for manufacturing a light-emitting device, comprising:
forming a first light-emitting element and a second light-emitting element on a connection board;
forming a first isolation structure between and around the first light-emitting element and the second light-emitting element;
forming a light-converting layer on the first light-emitting element and the second light-emitting element;
dicing the light-converting layer to form a plurality of light-converting segments that correspond to the first light-emitting element and the second light-emitting element;
forming a second isolation structure between and around the light-converting segments; and
connecting the connection board with a circuit board;
wherein a thermal expansion coefficient of the connection board is less than a thermal expansion coefficient of the circuit board.

20. The method for manufacturing the light-emitting device as claimed in claim 19, wherein the first isolation structure comprises a reflective or scattering material, and the second isolation structure comprises a light-absorbing material.
